(19) United States
(12) Patent Application Publication
(10) Pub. No.: US 2015/0212109 A1
(43) Pub. Date: Jul. 30, 2015

(54) MEMS SENSOR

(71) Applicant: SAMSUNG ELECTRO-MECHANICS CO., LTD., Gyeonggi-Do (KR)

(72) Inventors: In Young KANG, Gyeonggi-Do (KR); Jeong Suong YANG, Gyeonggi-Do (KR); Seung Mo LIM, Gyeonggi-Do (KR); Yun Sung KANG, Gyeonggi-Do (KR)

(73) Assignee: SAMSUNG ELECTRO-MECHANICS CO., LTD., Gyeonggi-Do (KR)

(21) Appl. No.: 14/341,457

(22) Filed: Jul. 25, 2014

(30) Foreign Application Priority Data
Jan. 29, 2014 (KR) 10-2014-0011518

(51) Int. Cl. G01P 15/09; H01L 41/09; B81B 3/00; G01L 1/16

(52) U.S. Cl. CPC G01P 15/0922; G01L 1/16; H01L 41/0973; B81B 3/0021; B81B 2201/0264; B81B 2201/0235

(57) ABSTRACT

Embodiments of the invention provide a MEMS sensor, including a flexible substrate having a vibrator and a sensor, a mass body coupled with the flexible substrate, and a support part supporting the flexible substrate. The vibrator includes a multilayer piezoelectric part and an electrode part connected to the multilayer piezoelectric part, and the sensor includes a piezoelectric material and an electrode part. The multilayer piezoelectric part is polled in the same direction and one of the piezoelectric materials contacting each other is expanded or contracted in an opposite direction to the other piezoelectric material. An uppermost layer of the vibrator and an uppermost layer of the sensor with respect to a stacking direction in which the piezoelectric material and the electrode part of the vibrator and the sensor are each stacked, are disposed on the same surface.

### CROSS REFERENCE TO RELATED APPLICATION:

This application claims the benefit of and priority under 35 U.S.C. §119 to Korean Patent Application No. KR 10-2014-0011518, entitled “MEMS SENSOR,” filed on Jan. 29, 2014, which is hereby incorporated by reference in its entirety into this application.

### BACKGROUND:

1. Field of the Invention

The invention relates to a micro electro mechanical system (MEMS sensor.

2. Description of the Related Art

MEMS is a technology of manufacturing an ultra-micro mechanical structure, such as a very large scale integrated circuit, an inertial sensor, a pressure sensor, and an oscillator, by processing silicon, crystal, glass, or the like. A MEMS component has precision of a Micrometer ( 1/1,000,000 meter) or less and may be structurally mass-produced as a micro product at a low cost by applying a semiconductor micro process technology of repeating processes, such as a deposition process and an etching process.

Further, among the MEMS components, the piezoelectric actuator applies an electric field to a piezoelectric material, such that the piezoelectric material is contracted and expanded. In this case, a diaphragm coupled with the piezoelectric material may be deformed by the contraction and expansion of the piezoelectric material.

Further, in order to improve a displacement or a vibration force, the piezoelectric actuator configured by the above method is implemented as a multilayer piezoelectric actuator in which a plurality of piezoelectric bodies are stacked.

However, the MEMS sensor according to the convention art, as described, for example, in U.S. Pat. No. 8,372,677, has problems in that in forming the piezoelectric actuator as the driving unit, it is very difficult to perform a polling process of the piezoelectric material and it is difficult to he formed in a multilayer to improve the driving force and the sensing sensitivity.

### SUMMARY:

Accordingly, embodiments of the invention have been made to provide a MEMS sensor, in which a vibration means or vibrator is formed in a multilayer including a multilayer piezoelectric material and a sensing means or sensor is formed in a single layer including the piezoelectric material, thereby improving a vibration three and sensing sensitivity.

Further, embodiments of the invention have been made in an effort to provide a MEMS sensor, in which a multilayer piezoelectric part polled in the same direction in forming a vibration means or vibrator is provided and one piezoelectric material adjacent to the piezoelectric material multi-layer piezoelectric material is contracted and expanded to be opposite to the other piezoelectric material to serve as a variable diaphragm for each other to obtain a large displacement, thereby improving driving performance and sensing sensitivity.

In addition, embodiments of the invention have been made in an effort to provide a MEMS sensor, in which in forming a vibration means or vibrator, a piezoelectric material is applied with an anti-phase signal to increase a driving voltage as large as two times and increase a displacement as large as two times so that the MEMS sensor is implemented in high performance, thereby improving driving performance and sensing sensitivity.

According to an embodiment of the invention, there is provided a MEMS sensor, including a flexible substrate having a vibrator and a sensor, a mass body coupled with the flexible substrate, and a support part supporting the flexible substrate. The vibrator includes a multilayer piezoelectric part and an electrode part connected to the multilayer piezoelectric part, and the sensor includes a piezoelectric material and an electrode part The multilayer piezoelectric to is polled in the same direction and one of the piezoelectric materials contacting each other is expanded or contracted in an opposite direction to the other piezoelectric material. An uppermost layer of the vibrator and an uppermost layer of the sensor with respect to a stacking direction in which the piezoelectric material and the electrode part of the vibrator and the sensor are each stacked, are disposed on the same surface.

According to an embodiment, the multilayer piezoelectric part of the vibrator includes a first piezoelectric material, a second piezoelectric material, which is stacked with the first piezoelectric material and is expanded or contracted in an opposite direction to the first piezoelectric material. According to an embodiment, the electrode part is connected to the first piezoelectric material and the second piezoelectric material.

According to an embodiment, the electrode part includes a first electrode connected to the first piezoelectric material, a second electrode connected to the second piezoelectric material, and a third electrode disposed between the first piezoelectric material and the second piezoelectric material.

According to an embodiment, a portion of the second electrode, which does not contact the support part, is exposed to the outside.

According to an embodiment, with respect to the stacking direction in which the vibrator is supported to the support part, the second electrode is disposed at a lower end of the vibrator and a portion thereof contacts the support part, the second piezoelectric material is formed on an upper portion of the second electrode, the third electrode is formed between the second piezoelectric material and the first piezoelectric material, the first piezoelectric material is formed on an upper portion of the third electrode, and the first electrode is formed on an upper portion of the first piezoelectric material.

According to an embodiment, an electrode in which the first electrode and the second electrode are connected is a ground electrode.

According to an embodiment, the piezoelectric material of the sensor is formed in a single layer and the electrode part is formed to be stacked on one surface of the piezoelectric material.

According to an embodiment, the sensor and the vibrator have the same thickness to the stacking direction in which the piezoelectric material and the electrode part are formed.

According to an embodiment, the electrode part of the sensor includes an upper electrode, which is formed on one surface of the piezoelectric material, an intermediate electrode, which is formed on the other surface of the piezoelectric material, and a lower electrode, and wherein the intermediate electrode is connected to the lower electrode.

According to an embodiment, the electrode part of the sensor includes an upper electrode which is formed on one surface of the piezoelectric material and an intermediate electrode, which is formed on the other surface of the piezoelectric

According to another embodiment of the invention, there is provided a MEMS sensor, including a flexible substrate having a first layer and a second layer, which is stacked on the first layer and is provided with a sensor and a vibrator, a mass body coupled with the flexible substrate, and a support part supporting the flexible substrate. According to an embodiment, the vibrator includes a multilayer piezoelectric material part and an electrode part connected to the multilayer piezoelectric material part, and the sensor includes a piezoelectric material and an electrode part. According to an embodiment, the multilayer piezoelectric part of the vibrator is polled in different directions and is coupled with the first layer to be expanded or contracted in the same direction, and an uppermost layer of the vibrator and an uppermost layer of the sensor with respect to a stacking direction in which the piezoelectric material and the electrode part of the vibrator and the sensor arc each stacked are disposed on the same surface.

According to an embodiment, the multilayer piezoelectric part of the vibrator includes a first piezoelectric material, a second piezoelectric material, which is stacked with the first piezoelectric material and is expanded or contracted in an opposite direction to the first piezoelectric material. According to an embodiment, the electrode part is connected to the first piezoelectric material and the second piezoelectric material.

According to an embodiment, the electrode part includes a first electrode connected to the first piezoelectric material, a second electrode connected to the second piezoelectric material, and a third electrode disposed between the first piezoelectric material and the second piezoelectric material.

According to an embodiment, with respect to the stacking direction n which the flexible substrate is supported to the support part, the second electrode is disposed at a lower end of the vibrator and a portion thereof contacts the support part, the second piezoelectric material is formed on an upper portion of the second electrode, the third electrode is formed between the second piezoelectric material and the first piezoelectric material, the first piezoelectric material is formed on an upper portion of the third electrode, and the first electrode is formed on an upper portion of the first piezoelectric material.

According to an embodiment, an electrode which is connected to the first electrode and the second electrode is applied with a voltage and a third electrode is applied with a voltage having a phase difference of 180° with respect to the voltage.

According to an embodiment, an electrode in which the first electrode and the second electrode are connected is a ground electrode.

According to an embodiment, the piezoelectric material of the sensor is formed in a single layer and the electrode part is formed to be stacked on one surface of the piezoelectric material.

According to an embodiment, the sensor and the vibrator have the same thickness to the stacking direction in which the piezoelectric material and the electrode part are formed.

According to an embodiment, the electrode part of the sensor includes an upper electrode which is formed on one surface of the piezoelectric material, an intermediate electrode, which is formed on the other surface of the piezoelectric material, and a lower electrode, and wherein the intermediate electrode is connected to the lower electrode.

According to an embodiment, the electrode part of the sensor includes an upper electrode, which is formed on one surface of the piezoelectric material and an intermediate electrode, which is formed on the other surface of the piezoelectric material.

Various objects, advantages and features of the invention will become apparent from the following description of embodiments with reference to the accompanying drawings.

### BRIEF DESCRIPTION OF DRAWINGS:

These and other features, aspects, and advantages of the invention are better understood with regard to the following Detailed Description, appended Claims, and accompanying Figures. It is to be rioted, however, that the Figures illustrate only various embodiments of the invention and are therefore not to be considered limiting of the invention's scope as it may include other effective embodiments as well.

FIG. 1 is a conceptual diagram schematically illustrating a basic principle of a piezoelectric actuator for an MEMS sensor according to a first embodiment of the invention.

FIGS. 2A to 2C are a schematic configuration diagram and a use state diagram of a piezoelectric actuator to which the basic principle illustrated in FIG. 1 is applied, according to the first embodiment of the invention.

FIG. 3 is a configuration diagram schematically illustrating the MEMS sensor according the first embodiment of the invention.

FIG. 4 is a configuration diagram schematically illustrating a MEMS sensor according to a second embodiment of the invention,

FIG. 5 is a configuration diagram schematically illustrating a MEMS sensor according to a third embodiment of the invention.

FIGS. 6A to 6C are a schematic configuration diagram and a use state diagram of a piezoelectric actuator for an MEMS sensor according to the second embodiment of the invention.

FIG. 7 is a configuration diagram schematically illustrating a MEMS sensor according to a fourth embodiment of the invention.

FIG. 8 is a configuration diagram schematically illustrating a MEMS sensor according to a fifth embodiment of the invention.

FIG. 9 is a configuration diagram schematically illustrating a MEMS sensor according to a sixth embodiment of the invention,

### DETAILED DESCRIPTION:

Advantages and features of the invention and methods of accomplishing the same will be apparent by referring to embodiments described below in detail in connection with the accompanying drawings. However, the invention is not limited to the embodiments disclosed below and may be implemented in various different forms. The embodiments are provided only for completing the disclosure of the invention and for fully representing the scope of the invention to those skilled in the art.

For simplicity and clarity of illustration, the drawing figures illustrate the general manner of construction, and descriptions and details of welI known features and techniques may be omitted to avoid unnecessarily obscuring the discussion of the described embodiments of the invention. Additionally elements in the drawing figures are not necessarily drawn to scale. For example, the dimensions of some of the elements in the figures may be exaggerated relative to other elements to help improve understanding of embodiments of the invention. Like reference numerals refer to like elements throughout the specification.

Hereinafter, various embodiments of the invention will be described in detail with reference to the accompanying drawings.

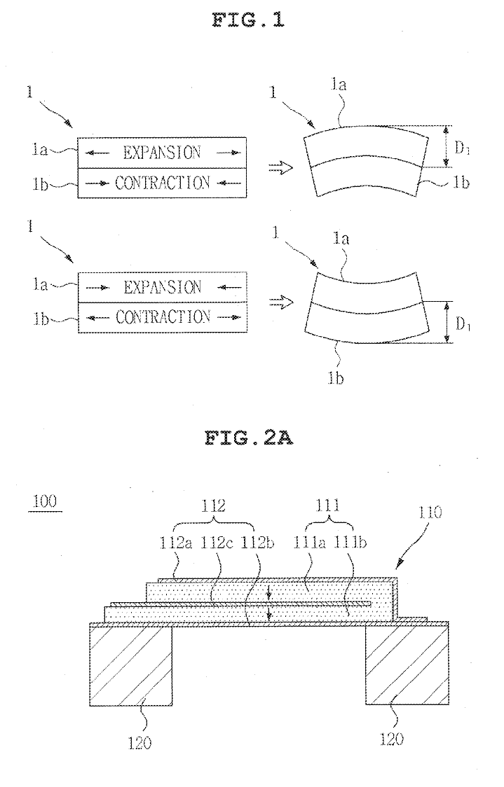

FIG. 1 is a conceptual diagram schematically illustrating a basic principle of a piezoelectric actuator for a MEMS sensor according to a first embodiment of the invention.

As illustrated in FIGS. 1A and 1B, a piezoelectric actuator 1 according to an embodiment of the invention includes a first piezoelectric material 1a and a second piezoelectric material 1b.

According to an embodiment, the first piezoelectric material 1a and the second piezoelectric material 1b are polled in the same direction as illustrated by an arrow and when being applied, with a voltage, the first piezoelectric material 1a and the second piezoelectric material 1b are expanded and contracted. In a direction opposite to each other. In more detail, when the first piezoelectric material 1a is expanded, the second piezoelectric material 1b is contracted and when the first piezoelectric material 1a is contracted, the second piezoelectric material 1b is expanded. /

Therefore, according to an embodiment, the first piezoelectric material 1a and the second piezoelectric material 1b serve as a vibration support plate for each other and serve as an active diaphragm which varies in an opposite direction.

According to an embodiment, when the first piezoelectric material 1a is expanded, the second piezoelectric material 1b is contracted and the first piezoelectric material 1a is more expanded, such that a protruding displacement occurs as illustrated by D1 and when the second piezoelectric material I b is expanded, the first piezoelectric material 1a is contracted and the second piezoelectric material 1b is more expanded, such that the protruding displacement occurs as illustrated by D1.

Consequently, in the piezoelectric actuator 1 for a MEMS sensor according to the first embodiment of the invention, the plurality of piezoelectric materials serve as the vibration support plate for each other and serve as an active diaphragm in which each piezoelectric material varies in an opposite direction to each other to generate a large displacement, thereby improving a vibration force.

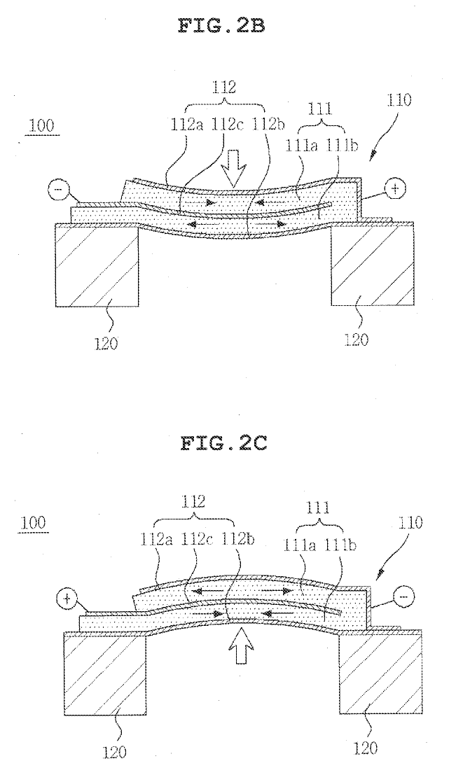

FIGS. 2A to 2C are a schematic configuration diagram an a use state diagram of a piezoelectric actuator to which the basic principle illustrated in FIG. 1 is applied as illustrated in FIGS. 2A to 2C, the piezoelectric actuator 100 includes a multilayer part 110 and a support part 120.

In more detail, the multilayer part 110 is applied with an electric field from the outside and thus is contracted and expanded to provide the vibration force and includes a multilayer piezoelectric part 111 and electrode part 112. Further, the support part 120 displaceably supports the multilayer part 110.

According to an embodiment, the multilayer piezoelectric part 111 is polled in the same direction as illustrated by an arrow in FIG. 2A and one piezoelectric material among the piezoelectric materials contacting each other is expanded or contracted in an opposite direction to the other piezoelectric material, thus, in a direction in which the piezoelectric materials are opposite to each other.

According to an embodiment, the multilayer piezoelectric part 111 includes a first piezoelectric material 111a and a second piezoelectric material 111b, in which the first piezoelectric material ilia is stacked on the second piezoelectric material 111b.

According to an embodiment, as the first piezoelectric material 111a and the second piezoelectric material 111b are not coupled with the support plate but ends thereof are supported to the support part 120, the first piezoelectric material 111a and the second piezoelectric material 111b are expanded or contracted in an opposite direction to each other.

According to an embodiment, the first piezoelectric material 11a and the second. piezoelectric material 111b serve as the vibration support plate for each other and serve as the active diaphragm which varies in an opposite direction.

The technology implementation thereof will be described below in more detail with reference to FIGS. 2B and 2C.

According to an embodiment, the electrode part 112 includes a first electrode 112a, a second electrode 112b, and a third electrode 112c. Which are each connected to the multilayer piezoelectric part 111.

According to an embodiment, the first electrode 112a is connected to the first piezoelectric material 111a, the second electrode 112b is connected to the second piezoelectric material 111b, and the third electrode 112c is disposed between the first piezoelectric material. 111a and the second piezoelectric material 111b.

According to an embodiment, an electrode which the first electrode 112a and the second electrode 112b are connected to each other is used as a ground electrode.

According to an embodiment, with respect to a stacking direction in which the multilayer part 110 is coupled with the support part 120, the second electrode 112b is disposed at a lower end of the multilayer part 110 and a portion thereof is coupled with the support part 120, the second piezoelectric material 111b is disposed on an upper portion of the second electrode 112b, the third electrode 112c is disposed between the second piezoelectric material 111b and the first piezoelectric material 111a, the first piezoelectric material 111a is disposed on an upper portion of the third electrode 112c, and the first electrode 112a is disposed on an upper portion of the first piezoelectric material 111a.

By the above configuration, in the multilayer part 110, the first electrode 112a is formed as an upper electrode, the second electrode 112b is formed as a lower electrode, and the third electrode 112c is formed as an intermediate electrode and the first electrode 112a is disposed on an uppermost layer of the multilayer part 110 and the second electrode 112b is disposed on a lowermost layer of the multilayer part 110.

According to an embodiment, the support part 120 is coupled with an end of the multilayer part to support the multilayer part 110 to be displaced. Therefore, a portion of the second electrode 112b, which does not contact the support part 120, is exposed to the outside.

Hereinafter, a driving principle and an operation state of the piezoelectric actuator will be described in more detail with reference to FIGS. 2B and 2C,

As illustrated in FIG. 2B, when an electric field is applied to the electrode in which the first electrode 112a and the second electrode 112b of the multilayer part 110 of the piezoelectric actuator 100 are connected to each other and the third electrode 112c, respectively, for example, when as represented by + and −, a positive voltage is applied to the electrode in which the first electrode 112a and the second electrode 112b are connected to each other and a negative voltage is applied to the third electrode, as illustrated by an arrow, the first piezoelectric material 111a is expanded and at the same time, the second piezoelectric material 111b is contracted.

Therefore, according to an embodiment, a central portion of the multilayer part 110 is displaced upward as represented by an arrow in the state in which an end thereof is supported to the support part 120.

Next, as illustrated in FIG. 2C, when an electric field opposite to that of FIG. 2B is applied to the electrode in Which the first electrode 111a and the second electrode 112b of the multilayer part 110 of the piezoelectric actuator 100 are connected to each other and the third electrode 112c, respectively, thus, when a negative voltage is applied to the electrode in which the first electrode 112a and the second electrode 112b are connected to each other and a positive voltage is applied to the third electrode, as represented by an arrow, the first piezoelectric material 111a is contracted and at the same time, the second piezoelectric material 111b is expanded.

Therefore, according to an embodiment, the central portion of the multilayer part 110 is displaced downward as represented by an arrow in the state in which the end thereof is supported to the support part 120.

By the above configuration, the first piezoelectric material 111a and the second piezoelectric material 111b are contracted and expanded to be opposite to each other, such that the large displacement occurs, thereby improving the driving performance.

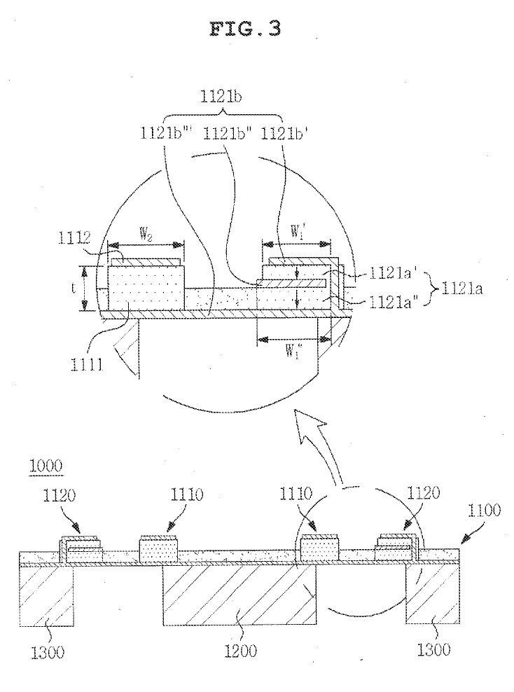

FIG. 3 is a configuration diagram schematically illustrating the MEMS sensor according to the first embodiment of the invention and as illustrated, the MEMS sensor 1000 includes a flexible substrate part 1100, a mass body 1200, and a support part 1300.

In more detail, the mass body 1200 is displaced by, for example, an inertial force, a Coriolis force, an external force, or a driving force, as non-limiting examples, and is coupled with the flexible substrate part 1100.

According to an embodiment, the flexible substrate part 1100 is provided with a sensing means or sensor 1100 (hereinafter referred to as a “sensing means” and a vibration means or vibrator 1120 (hereinafter referred to as a “vibration means”). According to an embodiment, as the flexible substrate part 1100 is coupled with the support part 1300, the mass body 1200 is displaceably supported to the support part 1300 in a floating state by the flexible substrate part 1100.

According to an embodiment, the vibration means 1120 is implemented as the piezoelectric actuator illustrated in FIG. 2A. Thus, according to an embodiment, the vibration means 1120 is formed in a multilayer including the plurality of piezoelectric layers.

According to an embodiment, the vibration means 1120 is applied with an electric field from the outside and is thus contracted or expanded, thereby providing the vibration force. Thus, the vibration means 1120 includes a multilayer piezoelectric part 1121a and an electrode part 1121b.

According to an embodiment, the multilayer piezoelectric part 1121a is polled in the same direction as illustrated by an arrow and one of the piezoelectric bodies contacting each other is expanded or contracted in an opposite direction to the other piezoelectric material.

According to an embodiment, the multilayer piezoelectric part 1121a includes a first piezoelectric material 1121a′ and a second piezoelectric material 1121a″, in which the first piezoelectric material 1121a′ is stacked on the second piezoelectric material 1121a″.

According to an embodiment, the first piezoelectric material 11211a′ and the second piezoelectric material 1121a″ are polled in the same direction to be expanded or contracted in an opposite to each other.

According to an embodiment, as the first piezoelectric material 1 121a′ and the second piezoelectric material 1121a″ are not coupled with the support plate, but only ends thereof are supported to the support part 1300, the first piezoelectric material 1121a′ and the second piezoelectric material 1121a″ are expanded or contracted in an opposite to each other.

According to an embodiment, the electrode part 1121b includes a first electrode 1121b′, a second electrode 1121b″, and a third electrode 1121b″, which are each connected to the multilayer piezoelectric part 1121a.

In more detail, the first electrode 1121b′ is connected to the first piezoelectric material 1121a′, the second electrode 1121b″ is connected to the second piezoelectric material 1121a″, and the third electrode 1121 b″ is disposed between the first piezoelectric material 1121a′ and the second piezoelectric material 1121a″.

According to an embodiment, the first electrode 1121b′ and the second electrode 1121b″ have ends connected to each other and is used as a ground electrode.

In more detail, with respect to the stacking direction in which the flexible substrate 1100 is coupled with the support part 1300, the second electrode 1121b″ is disposed at a lower end of the vibration means 1120 and a portion thereof contacts the support part 1300, the second piezoelectric material 1121a″ is disposed on an upper portion of the second electrode 1121b″, the third electrode 1121b″ is disposed between the second piezoelectric material 1121a″ and the first piezoelectric material 1121a′, the first piezoelectric material 1121a′ is disposed on at upper portion of the third electrode 1121b′″, and the first electrode 11 21b′ is disposed on an upper portion of the first piezoelectric material 1121a′.

By the above configuration, in the vibration means 1120, the first electrode 1121b′ is formed as an upper electrode, the second electrode 1121b″ is formed as a lower electrode, and the third electrode 1121b″ is formed as an intermediate electrode and the first electrode 1121b′ is disposed on an uppermost layer of the vibration means 1120 and the second electrode 1121b″ is disposed on a lowermost layer thereof,

According to an embodiment, the sensing means 1110 is to detect the displacement of the mass body 1200 and is adjacently formed to the mass body.

According to an embodiment, the sensing means 1110 is formed in a single layer including one piezoelectric layer. Thus, according to an embodiment, the sensing means 1110 is provided with the piezoelectric material 1111 and the upper electrode 1112 is formed on the piezoelectric material 1111.

According to an embodiment, the upper electrode 1112 of the sensing means 1110 and the first electrode 1121b′ of the vibration means 1120 is formed on the same surface.

In the MEMS sensor 1000 according to the first embodiment of the invention having the configuration, the piezoelectric material of the sensing means is formed in the single layer and the piezoelectric material of the vibration means is formed in the multilayer, thereby improving the driving force and the sensing sensitivity.

Thus

$${V}_{s} = \frac{{Q}_{s}}{{C}_{s}} and {C}_{s} = {ɛ}_{o} {ɛ}_{r} \frac{A}{d}$$

In the above Equation, since V_{S} corresponding to the sensing sensitivity is proportional to Q_{S} corresponding to the area of the piezoelectric material of the driving unit side and is inversely proportional to C_{S} corresponding to an area A of the piezoelectric material of the sensing unit side, to improve the sensing sensitivity, the area of the piezoelectric material of the driving unit side needs to be large and the area of the piezoelectric material of the sensing unit side needs to be small. Further, the sensing sensitivity is proportional to a thickness d of the piezoelectric material of the sensing unit side.

Therefore, as the vibration means 1120 of the MEMS sensor 1000 is formed in the multilayer, the area becomes W₁+W₁″ and as the piezoelectric material 1111 of the sensing means 1110 is formed in the single layer, the area becomes W₂, such that the area of the vibration means is approximately as large as two times, thereby improving the sensing sensitivity,

According to an embodiment, as a thickness I of the sensing means 1110 is also formed to be large, the sensing sensitivity is more improved.

According to the configuration as described above, the MEMS sensor according to the first embodiment of the invention includes the vibration means formed of the piezoelectric material of the multilayer and the sensing means formed of the piezoelectric material of the single layer, such that the MEMS sensor with the improved vibration force and the improved sensing sensitivity is obtained.

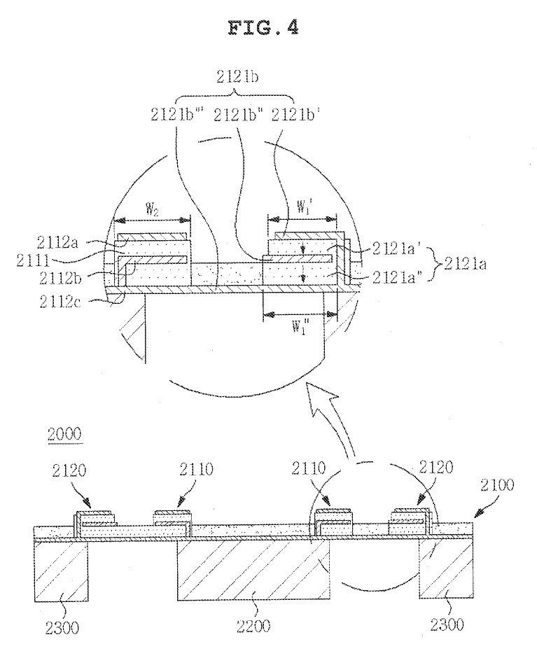

FIG. 4 is a configuration diagram schematically illustrating a MEMS sensor according to a second embodiment of the invention, and as illustrated in FIG. 4, a MEMS sensor 2000 is different from only the sensing means as compared with the MEMS sensor 1000 according to the first embodiment illustrated in FIG. 3.

100931 In more detail, the MEMS sensor 2000, according to the second embodiment of the invention, includes a flexible substrate part 2100, a mass body 2200, and a support part 2300.

In more detail, the mass body 2200 is coupled with the flexible substrate part 2100 and the flexible substrate part 2100 is provided with a sensing means 2110 and a vibration means 2120. Further as the flexible substrate part 2100 is coupled with the support part 2300, the mass body 2200 is displaceably supported to the support part 2300 in a floating state by the flexible substrate part 2100,

According to an embodiment, the sensing means 2110 is formed in the multilayer and an intermediate electrode is connected to a lower electrode and thus is formed of a piezoelectric material 2111 of the single layer. Thus, the sensing means 2110 is provided with the piezoelectric material 2111, an upper electrode 2112a is formed on the piezoelectric material 2111, and an intermediate electrode 2112b is connected to a lower electrode 2112c.

According to an embodiment, the vibration means 2120 is implemented to be the same as the vibration means 1120 illustrated in FIG. 3. Thus, the vibration means 2120 includes a multilayer piezoelectric part 1121a and an electrode part 1121b. Further, the multilayer piezoelectric part 2121a includes a first piezoelectric material 2121a′ and a second piezoelectric material 2121a″, in which the first piezoelectric material 2121a′ is stacked on the second piezoelectric material 2121a″,

According to an embodiment, the first piezoelectric material 2121a′ and the second piezoelectric material 2121a″ are polled in the same direction as illustrated in an arrow to be expanded or contracted in an opposite direction to each other.

According to an embodiment, as the first piezoelectric material 2121a′ and the second piezoelectric material 2121a″ are not coupled with the support plate but only ends thereof are supported to the support part 2300, the first piezoelectric material 2121a′ and the second piezoelectric material 2121a″ are expanded or contracted in an opposite to each other.

According to an embodiment, the electrode part 2121b includes a first electrode 2121b′, a second electrode 2121b″, and a third electrode 2121b″ which are each connected to the multilayer piezoelectric part 2121a.

In more detail, the first electrode 2121b′ is connected to the first piezoelectric material 2121a′, the second electrode 2121b″ is connected to the second piezoelectric material 2121a″, and the third electrode 2121b″ is disposed between the first piezoelectric material 2121a′ and the second piezoelectric material 2121a″.

According to an embodiment, the first electrode 2121b′ and the second electrode 2121b″ have ends connected to each other and is used as a ground electrode.

By the above configuration, in the vibration means 2120, the first electrode 2121b′ is formed as an upper electrode, the second electrode 212b″ is formed as a lower electrode, and the third electrode 2121b″ is formed as an intermediate electrode and the first electrode 2121b′ is disposed on an uppermost layer of the vibration means 2120 and the second electrode 2121b″ is disposed on a lowermost layer of the multilayer part 2121.

By the above configuration, as the piezoelectric material of the vibration means 2120 of the MEMS sensor 2000 according to the second embodiment of the invention is formed in the multilayer, the area becomes W₁′+W₁″ and as the piezoelectric material of the sensing means 2110 is formed in the multilayer or he intermediate electrode is connected to the lower electrode to be recognized as the piezoelectric material 2111 of the single layer, the area becomes W₂, such that the area of the vibration means is approximately as large as two times, thereby improving the sensing sensitivity.

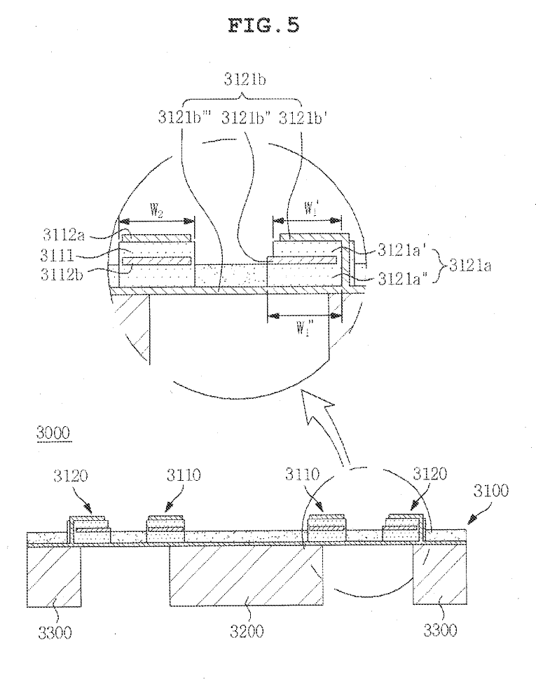

FIG. 5 is a configuration diagram schematically illustrating a MEMS sensor according to a third embodiment of the invention, and as illustrated in FIG. 5, a MEMS sensor 3000 is different from only the sensing means, as compared with the MEMS sensor 1000 according to the first embodiment illustrated in FIG. 3.

In more detail, the MEMS sensor 3000 includes a flexible substrate part 3100, a mass body 3200, and a support part 3300.

In more detail, the mass body 3200 is coupled with the flexible substrate part 3100 and the flexible substrate part 3100 is provided with a sensing means 3110 and a vibration means 3120. Further, as the flexible substrate part 3100 is coupled with the support part 3300, the mass body 3200 is displaceably supported to the support part 3300 in a floating state by the flexible substrate part 3100.

According to an embodiment, the sensing means 3110 is formed in the multilayer and the intermediate electrode is formed to be recognized as a piezoelectric material 3111 of the single layer. Thus, the sensing means 2110 is provided with the piezoelectric material 3111 and an upper electrode 3112a is formed on one surface of the piezoelectric material 3111 and an intermediate electrode 3112b is formed on the other surface thereof.

According to an embodiment, the vibration means 3120 is implemented to be the same as the vibration means 1120 illustrated in FIG. 3. Thus, the vibration means 3120 includes a multilayer piezoelectric part 3121 a and an electrode part 3121b. Further, the multilayer piezoelectric part 3121a includes a first piezoelectric material 3121a′ and a second piezoelectric material 3121a″, in which the first piezoelectric material 3121a′ is stacked on the second piezoelectric material 3121a″.

According to an embodiment, the first piezoelectric material 3121a′ and the second piezoelectric material 3121a″ are polled in the same direction as illustrated in an arrow to be expanded or contracted in an opposite direction o each other.

According to an embodiment, as the first piezoelectric material 3121a′ and the second piezoelectric material 3121a″ are not coupled with the support plate but only ends thereof are supported to the support part 3300, the first piezoelectric material 3121a′ and the second piezoelectric material 3121a″ are expanded or contracted in an opposite to each other.

According to an embodiment, the electrode part 3121b includes a first electrode 3121b′, a second electrode 3121b″, and a third electrode 3121b″, which are each connected to the multilayer piezoelectric part 3121a.

In more detail, the first electrode 3121b′ is connected to the first piezoelectric material 3121a′, the second electrode 3121b″ is connected to the second piezoelectric material 3121a″, and the third electrode 3121b″ is disposed between the first piezoelectric material 3121a′ and the second piezoelectric material 3121a″.

According to an embodiment, the first electrode 3121b′ and the second electrode 3121b″ have ends connected to each other and is used as a ground electrode.

By the above configuration, in the vibration means 3120, the first electrode 3121b′ is formed as an upper electrode, the second electrode 3121b″ is formed as a lower electrode, and the third electrode 3121b″ is formed as the intermediate electrode and the first electrode 3121b′ is disposed on an uppermost layer of the vibration means 3120 and the second electrode 3121b″ is disposed on a lowermost layer thereof

By the above configuration, as the piezoelectric material of the vibration means 2120 of the MEMS sensor 2000 according to the second embodiment of the invention is formed in the multilayer, the area becomes W₁′+W₁″ and as the piezoelectric material of the sensing means 3110 is formed in the multilayer or the intermediate electrode is formed to be recognized as the piezoelectric material 3111 of the single layer, the area becomes W₂, such that the area of the vibration means is approximately as large as two times, thereby improving the sensing sensitivity.

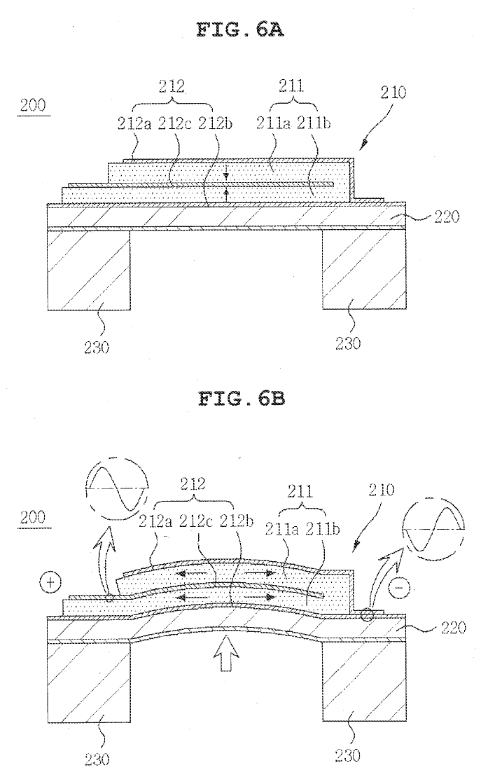

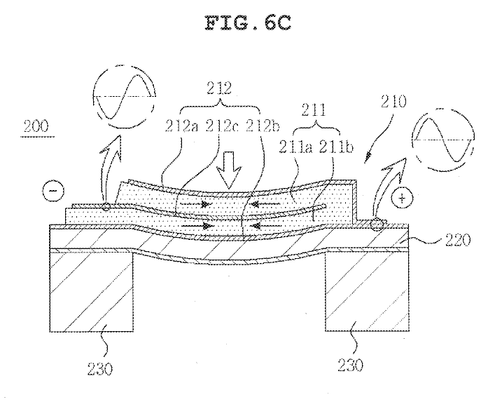

FIGS. 6A to 6C are a schematic configuration diagram and a use state diagram of a piezoelectric actuator for an MEMS sensor according to the second embodiment of the invention. As illustrated in these figures, the piezoelectric actuator 200 includes a multi-layer part 210, a support layer 220, and a support part 230.

In more detail, the multi-layer part 210 is coupled with the support layer 220 and the support layer 220 is displaceably supported to the support part 230

According to an embodiment, the multi--layer part 210 is contracted or expanded by being applied with a voltage having a phase difference to provide a vibration force and includes a multilayer piezoelectric part 211 and an electrode part 212.

According to an embodiment, the multilayer piezoelectric part 211 includes a first piezoelectric material 211a and a second piezoelectric material 211b, in which the first piezoelectric material 211a is stacked on the second piezoelectric material 211b.

According to an embodiment, the first piezoelectric material 211a and the second piezoelectric material 211b are polled in different directions as illustrated by an arrow.

According to an embodiment, the electrode part 212 which is connected to the first piezoelectric material 211a and the second piezoelectric material 211b is applied with a voltage having a phase difference of 180°, such that the first piezoelectric material 211a and the second piezoelectric material 211b are expanded or contracted in the same direction.

The technology implementation thereof will be described below in more detail with reference to FIGS. 6B and 6C.

According to an embodiment, the electrode part 212 includes a first electrode 212a, a second electrode 212b, and a third electrode 212c, which are each connected to the multilayer piezoelectric part 211.

According to an embodiment, the first electrode 212a is connected to the first piezoelectric material 211a, the second electrode 212b is connected to the second piezoelectric material 211b, and the third electrode 212c is disposed between the first piezoelectric material 211a and the second pizoelectric material 211b.

According to an embodiment, the first electrode 212a and the second electrode 212b have ends connected to each other.

According to an embodiment, the third electrode 212c is used as the ground electrode.

In more detail, with respect to a stacking direction in which the multilayer part 210 is coupled with the support part 220, the second electrode 212b is disposed at a lower end of the multilayer part 210 to be coupled with the support part 220, the second piezoelectric material 211b is disposed on an upper portion, of the second electrode 212b, the third electrode 212c is disposed between the second piezoelectric material 211b and the first piezoelectric material 211a, the first piezoelectric material 211a is disposed on an upper portion of the third electrode 212c, and the first electrode 212a is disposed on an upper portion of the first piezoelectric material 211a.

By the above configuration, in the multi-layer part 210, the first electrode 212a is formed of an upper electrode, the second electrode 212b is formed of a lower electrode, and the third electrode 212c is formed of an intermediate electrode, the first electrode 212a is disposed on a top layer of the multi-layer part 210, and the second electrode 212b is disposed on a bottom layer of the multi-layer part 210.

According to an embodiment, the support part 230 is coupled with the support layer 220 to support the end of the support layer so that the support layer 220 is displaced,

Hereinafter, a driving principle, and an operation, state of the piezoelectric actuator will be described in more detail with reference to FIGS. 6B and 6C,

As illustrated in FIG. 6B, the electrode to which the first electrode 212a and the second electrode 212b of the multilayer part 210 of the piezoelectric actuator 200 are connected is applied with a voltage and the third electrode 212c is applied with a voltage having an anti-phase to the voltage, thus, the voltage having a phase difference of 180°. Thus, the first electrode 212a and the second electrode 212b are applied with the same voltage and the third electrode 212c is applied with a voltage having a phase difference of 180° with respect to the voltage.

Therefore, as illustrated by an arrow, the same first piezoelectric material 211a and second piezoelectric material 211b are expanded or contracted in the same direction.

According to an embodiment, as the piezoelectric part 211 and the electrode part 212 are coupled with the support layer 220, the central portions of the multilayer part 210 and the support layer 220 are displaced upward,

According to an embodiment, as illustrated in FIG. 6C, the electrode to which the first electrode 212a and the second electrode 212b of the multilayer part 210 of the piezoelectric actuator 200 are connected and the third electrode 212c are each applied with an anti-phase voltage opposite to FIG. 6B. In this case, as illustrated by an arrow, the first piezoelectric material 211a and the second piezoelectric material 211b are simultaneously contracted.

According to an embodiment, as the piezoelectric part 211 and the electrode part 212 are coupled with the support layer 220, the central portions of the multilayer part 210 and the support layer 220 are displaced downward.

By the above configuration, the multilayer piezoelectric part applies a voltage having a phase difference of 180° to the upper electrode and the lower electrode to generate a displacement as large as two times and as the first piezoelectric material and the second piezoelectric material are formed in two layers, a displacement as large as four times is generated and thus is implemented as a high-performance piezoelectric actuator,

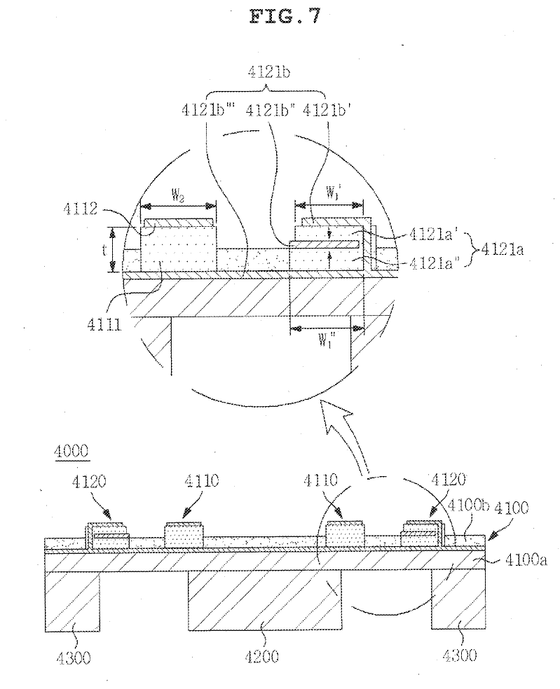

FIG. 7 is a configuration diagram schematically illustrating a MEMS sensor according to a fourth embodiment of the invention, and as illustrated in FIG. 7, a MEMS sensor 4000 includes the piezoelectric actuator illustrated in FIG. 6A as the vibration means and includes a flexible substrate part 4100, a mass body 4200, and a support part 4300.

In more detail, the mass body 4200 is coupled with the flexible substrate part 4100.

According to an embodiment, the flexible substrate part 4100 includes a first layer 4100a and a second layer 4100b which is stacked on the first layer 4100a and provided with a sensing means 4110 and a vibration means 4120, in which the first layer 4100a serves as a support layer of the vibration means 4120.

According to an embodiment, as the flexible substrate part 4100 is coupled with the support part 4300, the mass body 4200 is displaceably supported to the support part 4300 in a floating state by the flexible substrate part 4100.

According to an embodiment, as described above, the vibration means 4120 is implemented as the piezoelectric actuator illustrated in FIG. 6A and the vibration means 4120 is implemented as the multilayer part including the multilayer piezoelectric material.

According to art embodiment, the vibration means 4120 is applied with an electric field from the outside and is thus contracted or expanded, thereby providing the vibration force. To this end, the vibration means 4120 includes a multilayer piezoelectric part 4121a and an electrode part 4121′b.

According to an embodiment, the multilayer piezoelectric part 4121a is polled in different directions as illustrated by an arrow and the multilayer piezoelectric part 4121a is expanded or contracted in the same direction in the state which the multilayer piezoelectric part 4121a is attached to the support layer 4100a, thereby generating the vibration force.

According to an embodiment, the multilayer piezoelectric part 4121a includes a first piezoelectric material 4121a′ and a second piezoelectric material 4121a″, in which the first piezoelectric material 4121a′ is stacked on the second piezoelectric material 4121a″.

According to an embodiment, the first piezoelectric material 4121a′ and the second piezoelectric material 4121a″ are polled in different directions, thus, as illustrated in an arrow to be expanded or contracted in the same direction as each other.

According to an embodiment, the first piezoelectric material 4121a′ and the second piezoelectric material 4121a″ are coupled with the first layer 4100a and are expanded or contracted in the same direction as each other, thereby providing the driving force.

According to an embodiment, the electrode part 4121b includes a first electrode 4121b ′, a second electrode 4121b″, and a third electrode 4121b″ which are each connected to the multilayer piezoelectric part 4121a.

In more detail, the first electrode 4121b′ is connected to the first piezoelectric material 4121a′, the second electrode 4121b″ is connected to the second piezoelectric material 4121a″, and the third electrode 4121b′″ is disposed between the first piezoelectric material 4121a′ and the second piezoelectric material 4121a″.

In more detail, with respect to the stacking direction in which the flexible substrate 4100 is coupled with the support part 4300, the second electrode 4121b″ is disposed at a lower end of the vibration means 4120, the second piezoelectric material 4121a″ is disposed on an upper portion of the second electrode 4121b″, the third electrode 4121b′″ is disposed between the second piezoelectric material 4121a″ and the first piezoelectric material 4121a′, the first piezoelectric material 4121a′ is disposed on an upper portion of the third electrode 4121b″, and the first electrode 4121b′ is disposed on an upper portion of the first piezoelectric material 4121a′.

By the above configuration, in the vibration means 4120, the first electrode 4121b′ is formed as an upper electrode, the second electrode 4121b″ is formed as a lower electrode, and the third electrode 4121b″ is formed as an intermediate electrode and the first electrode 4121b′ is disposed on an uppermost layer of the vibration means 4120 and the second electrode 4121b″ is disposed on a lowermost layer thereof.

According to an embodiment, the sensing means 4110 is formed in the single layer including one piezoelectric material. Thus, the sensing means 4110 is provided with the piezoelectric material 4111 and the upper electrode 4112 is formed on the piezoelectric material 4111.

According to an embodiment, the upper electrode 4110 of the sensing means 4112 and the first electrode 4121b′ of the vibration means 4120 is formed on the same surface.

Therefore, as the piezoelectric material of the vibration means 4120 of the MEMS sensor 4000 is formed in the multilayer, the area becomes W₁′+W₁″ and as the piezoelectric material of the sensing means 4110 is formed in the single layer, the area becomes W₂, such that the area of the vibration means is approximately as large as two times, thereby improving the sensing sensitivity.

According to an embodiment, as a thickness of the sensing means 2110 is also formed to be large, the sensing sensitivity is more improved.

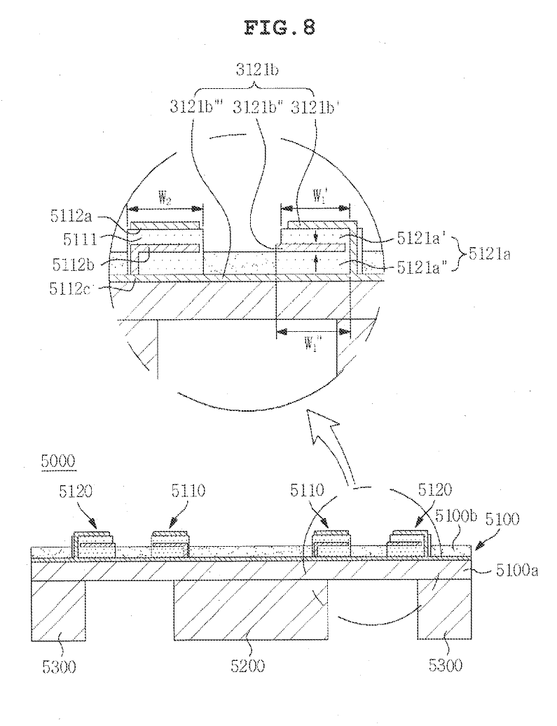

FIG. 8 is a configuration diagram schematically illustrating a MEMS sensor according to a fifth embodiment of the invention. As illustrated in FIG. 4, a MEMS sensor 5000 is different from only the sensing means, as compared with the MEMS sensor 4000 according to the fourth embodiment illustrated in FIG. 7.

In more detail, the MEMS sensor 5000 includes a flexible substrate part 5100, a mass body 5200, and a support part 5300.

According to an embodiment, the mass body 5200 is coupled with the flexible substrate part 5100.

According to an embodiment, the flexible substrate part 5100 includes a first layer 5100a and a second layer 5100b which is stacked on the first layer 5100a and provided with a sensing means 5110 and a vibration means 5120, in which the first layer 5100a serves as a support layer of the vibration and 5170.

According to an embodiment, as the flexible substrate part 5100 is coupled with the support part 5300, the mass body 5200 is displaceably supported to the support part 5300 in a floating state by the flexible substrate part 5100,

According to an embodiment, the vibration means 5120 is applied with an electric field from the outside and is thus contracted or expanded, thereby providing the vibration force. According to embodiment, the vibration means 5120 includes a multilayer piezoelectric part 5121a and an electrode part 5121b.

According to an embodiment, the multilayer piezoelectric part 5121a is polled in different directions as illustrated by an arrow and the multilayer piezoelectric part 5121a is expanded or contracted in the same direction in the state in which the multilayer piezoelectric part 5121a is attached to the support layer 5100a, thereby generating the vibration force.

According to an embodiment, the multilayer piezoelectric part 5121 a includes a first piezoelectric material 5121a′ and a second piezoelectric material 5121a″, in which the first piezoelectric material 5121a′ is stacked on the second piezoelectric material 5121a″.

According to an embodiment, the first piezoelectric material 5121a′ and the second piezoelectric material 5121a″ are polled in different directions, thus, as illustrated in an arrow to be expanded or contracted in the same direction as each other,

According to an embodiment, the first piezoelectric material 5121a′ and the second piezoelectric material 5121a″ are coupled with the first layer 5100a and are expanded or contracted in the same direction as each other, thereby providing the driving force.

According to an embodiment, the electrode part 5121b includes a first electrode 5121b′, a second electrode 5121b″, and a third electrode 5121b′″ which are each connected to the multilayer piezoelectric part 5121a.

In more detail, the first electrode 5121b′ is connected to the first piezoelectric material 5121 , the second electrode 5121b″ is connected to the second piezoelectric material 5121a″, and the third electrode 5121b″ is disposed between the first piezoelectric material 5121a′ and the second piezoelectric material 5121a″.

In more detail, with respect to the stacking direction in which the flexible substrate 5100 is coupled with the support part 5300, the second electrode 5121b″ is disposed at a lower end of the vibration means 5121, the second piezoelectric material 5121a″ is disposed on an upper portion of the second electrode 5121b″, the third electrode 5121b′″ is disposed between the second piezoelectric material 5121a″ and the first piezoelectric material 5121a′, the first piezoelectric material 5121a is disposed on an upper portion of the third electrode 5121b′″, and the first electrode 5121b′ is disposed on an upper portion of the first piezoelectric material 5121a′,

By the above configuration, in the vibration means 5121, the first electrode 2121b′ is formed as an upper electrode, the second electrode 5121b″ is formed as a lower electrode, and the third electrode 5121b″ is formed as an intermediate electrode and the first electrode 5121b′ is disposed on an uppermost layer of the vibration means 51201 and the second electrode 5121b″ is disposed on a lowermost layer thereof.

According to an embodiment, the piezoelectric material of the sensing means 5110 is formed in the multilayer and the intermediate electrode is connected to the lower electrode and thus is formed of the piezoelectric material 5111 of the single layer. Thus, the sensing means 5110 is provided with the piezoelectric material 5111, an upper electrode 5112a is formed on the piezoelectric material 5111, and an intermediate electrode 5112b is connected to a lower electrode 5112c.

According to an embodiment, the upper electrode 5112 of the sensing means 5110 and the first electrode 5121b′ of the vibration means 5120 is formed on the same surface.

By the above configuration, as the piezoelectric material of the vibration means 5120 of the MEMS sensor 5000 according to the second embodiment of the invention is formed in the multilayer, the area becomes W₁′+W₁″ and as the piezoelectric material of the sensing means 5110 is formed in the multilayer or the intermediate electrode is connected to the lower electrode to be recognized as the piezoelectric material 5111 of the single layer, the area becomes W₂, such that the area of the vibration means is approximately as large as two times, thereby improving the sensing sensitivity.

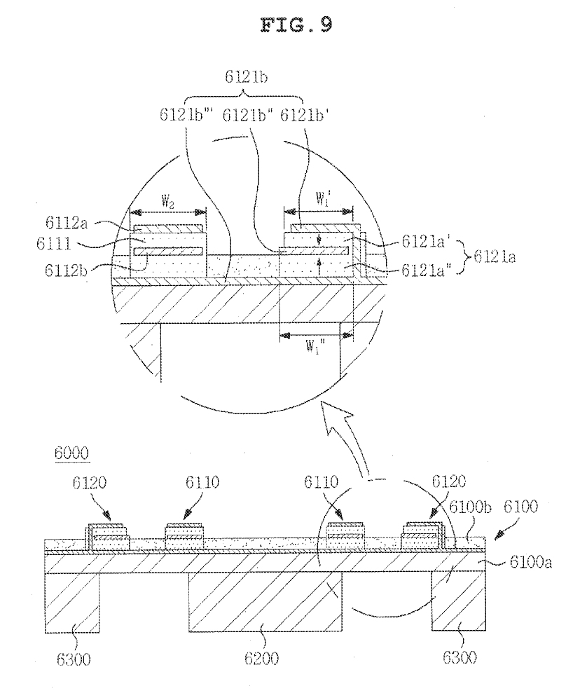

FIG. 9 is a configuration diagram schematically illustrating a MEMS sensor according to a sixth embodiment of the invention.

According to an embodiment, the MEMS sensor 6000 is different from only the sensing means, as compared with the MEMS sensor 4000 according to the fourth embodiment illustrated in FIG. 7.

In more detail, the MEMS sensor 6000 includes a flexible substrate part 6000, a mass body 6200, and a support part 6300.

In more detail, the mass body 6200 is coupled with the flexible substrate part 6100,

According to an embodiment, the flexible substrate part 6100 includes a first layer 6100a and a second layer 6100b which is stacked on the first layer 6100a and provided with a sensing means 6110 and a vibration means 6120, in which the first layer 6100a serves as a support layer of the vibration means 6120.

According to an embodiment, as the flexible substrate part 6100 is coupled with the support part 6300, the mass body 5200 is displaceably supported to the support part 6300 in a floating state by the flexible substrate part 6100,

According to an embodiment, the vibration means 6120 is formed of the multilayer part including the multilayer piezoelectric material and is applied with an electric field from the outside and thus contracted or expanded, thereby providing the vibration force. To this end, the vibration means 6120 includes a multilayer piezoelectric part 6121a and an electrode part 6121b.

According to an embodiment, the multilayer piezoelectric part 6121a is polled in different directions as illustrated by an arrow and the multilayer piezoelectric part 6121a is expanded or contracted in the same direction in the state in which the multilayer piezoelectric part 6121a is attached to the support layer 6100a, thereby generating the vibration force.

According to an embodiment, the multilayer piezoelectric part 6121a includes a first piezoelectric material 6121a′ and a second piezoelectric material 6121a″, in which the first piezoelectric material 6121a′ is stacked on the second piezoelectric material 6121a″,

According to an embodiment, the first piezoelectric material 6121a′ and the second piezoelectric material 6121a″ are polled in different directions, thus, as illustrated in an arrow to be expanded or contracted in the same direction as each other.

According to an embodiment, the first piezoelectric material 6121a′ and the second piezoelectric material 6121a″ are coupled with the first layer 6100a and are expanded or contracted in the same direction as each other, thereby providing the driving force.

According to an embodiment, the electrode part 6121b includes a first electrode 6121f, a second electrode 6121b″, and a third electrode 6121b″, which are each connected to the multilayer piezoelectric part 6121a.

In more detail, the first electrode 6121b′ is connected to the first piezoelectric material 6211a′, the second electrode 6121b″ is connected to the second piezoelectric material 6121a″, and the third electrode 6121b″ is disposed between the first piezoelectric material 6121a′ and the second piezoelectric material 6121a″.

In more detail, with respect to the stacking direction in which the flexible substrate 6100 is coupled with the support part 6300, the second electrode 6121b″ is disposed at a lower end of the vibration means 6121, the second piezoelectric material 6121a″ is disposed on an upper portion of the second electrode 6121b″, the third electrode 6121b″ is disposed between the second piezoelectric material 6121a″ and the first piezoelectric material 6121a′, the first piezoelectric material 6121a′ is disposed on an upper portion of the third electrode 6121b″, and the first electrode 6121b′ is disposed on an upper portion of the first piezoelectric Material 6121a′.

By the above configuration, in the vibration means 6120, the first electrode 6121b′ is formed as an upper electrode, the second electrode 6121b″ is formed a′s a to lower electrode, and the third electrode 6121b″ is formed as an intermediate electrode and the first electrode 6121b′ is disposed on an uppermost layer of the vibration means 6120 and the second electrode 6121b″ is disposed on a lowermost layer thereof

According to an embodiment, the sensing means 6110 is formed in the multilayer and the intermediate electrode is formed to be recognized as the piezoelectric material 6111 of the single layer. Thus, the sensing means 6110 is provided with the piezoelectric material 6111 and an upper electrode 6112a is formed on one surface of the piezoelectric material 6111 and an intermediate electrode 6112b is formed on the other surface thereof.

According to an embodiment, the upper electrode 6110 of the sensing means 6112 and the first electrode 6121b′ of the vibration means 6120 is formed on the same surface.

By the above configuration, as the vibration means 2120 of the MEMS sensor 2000 according to the second embodiment of the invention is formed in the multilayer, the area becomes W₁′+W₁″ and as the piezoelectric material of the sensing means 3110 is formed in the multilayer or the intermediate electrode is formed to be recognized as the piezoelectric material 3111 of the single layer, the area becomes W₂, such that the area of the vibration means is approximately as large as two times, thereby improving the sensing sensitivity.

According to various embodiments of the invention, it is possible to obtain the MEMS sensor, in which the vibration means is formed in the multilayer including the multilayer piezoelectric material and the sensing means is formed in the single layer including the piezoelectric material, thereby improving the vibration force and the sensing sensitivity, the multilayer piezoelectric part polled in the same direction in forming the vibration means is provided and one piezoelectric material adjacent to the piezoelectric material in the multilayer piezoelectric material is contracted and expanded to be opposite to the other piezoelectric material to serve as the variable diaphragm for each other to obtain the large displacement, thereby improving the driving performance and the sensing sensitivity, and the piezoelectric material is applied with the anti-phase signal in forming the vibration means to increase the driving voltage as large as two times and increase the displacement as large as two times so that the MEMS sensor is implemented in high performance, thereby improving the driving performance and the sensing sensitivity.

Terms used herein are provided to explain embodiments, not limiting the invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the invention may suitably comprise, consist or consist essentially of the elements disclosed and may be practiced in the absence of an element not disclosed. For example, it can be recognized by those skilled in the art that certain steps can be combined into a single step.

The terms and words used in the specification and claims should not be interpreted as being limited to typical meanings or dictionary definitions, but should be interpreted as having meanings and concepts relevant to the technical scope of the invention based on the rule according to which an inventor can appropriately define the concept of the term to describe the best method he or she knows for carrying out the invention.

The terms “first.” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may he performed, and certain of the stated steps may possibly be omitted and/or certain there steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein art, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the invention has been described in detail, it should be understood that various changes, substitutions, and alterations can be made hereupon without departing from the principle and scope of the invention. Accordingly, the scope of the invention should be determined by the following claims and their appropriate legal equivalents.

What is claimed is:

1. A MEMS sensor, comprising:
a flexible substrate comprising a vibrator and a sensor;
a mass body coupled with the flexible substrate; and
a support part supporting the flexible substrate,
wherein the vibrator comprises a multilayer piezoelectric part and an electrode part connected to the multilayer piezoelectric part, and the sensor comprises a piezoelectric material and an electrode part,
wherein the multilayer piezoelectric part is polled in the same direction and one of the piezoelectric materials contacting each other is expanded or contracted in an opposite direction to the other piezoelectric material, and
wherein an uppermost layer of the vibrator and an uppermost layer of the sensor with respect to a stacking direction in which the piezoelectric material and the electrode part of the vibrator and the sensor are each stacked, are disposed on the same surface.

2. The MEMS sensor as set forth in claim 1, wherein the multilayer piezoelectric part of the vibrator comprises:
a first piezoelectric material, a second piezoelectric material, which is stacked with the first piezoelectric material and is expanded or contracted in an opposite direction to the first piezoelectric material,
wherein the electrode part is connected to the first piezoelectric material and the second piezoelectric; material.

3. The MEMS sensor as set forth in claim 2, wherein the electrode part comprises a first electrode connected to the first piezoelectric material, a second electrode connected to the second piezoelectric material, and a third electrode disposed between the first piezoelectric material and the second piezoelectric material.

4. The MEMS sensor as set forth in claim 3, wherein a portion of the second electrode, which does not contact the support part, is exposed to the outside,

5. The MEMS sensor as set forth in claim 3, wherein with respect to the stacking direction in which the vibrator is supported to the support part,
the second electrode is disposed at a lower end of the vibrator and a portion thereof contacts the support part,
the second piezoelectric material is formed on an upper portion of the second electrode,
the third electrode is formed between the second piezoelectric material and the first piezoelectric material,
the first piezoelectric material is formed on an upper portion of the third electrode, and the first electrode is formed on an upper portion of the first piezoelectric material.

6. The MEMS sensor as set forth in claim 5, wherein an electrode in which the first electrode and the second electrode are connected is a ground electrode.

7. The MEMS sensor as set forth in claim 1, wherein the piezoelectric material of the sensor is formed in a single layer and the electrode part is formed to be stacked on one surface of the piezoelectric material.

8. The MEMS sensor as set forth in claim 1, wherein the sensor and the vibrator have the same thickness to the stacking direction in which the piezoelectric material and the electrode part are formed,

9. The MEMS sensor as set forth in claim 1, wherein the electrode part of the sensor comprises an upper electrode, which is formed on one surface of the piezoelectric material, an intermediate electrode, which is formed on the other surface of the piezoelectric material, and a lower electrode, and wherein the intermediate electrode is connected to the lower electrode,

10. The MEMS sensor as set forth in claim 1, wherein the electrode part of the sensor comprises an upper electrode which is formed on one surface of the piezoelectric material and an intermediate electrode, which is formed on the other surface of the piezoelectric material.

11. A MEMS sensor, comprising:
a flexible substrate comprising a first layer and a second layer, which is stacked on the first layer and is provided with a sensor and a vibrator;
a mass body coupled with the flexible substrate; and
a support part supporting the flexible substrate,
wherein the vibrator comprises a multilayer piezoelectric material part and an electrode part connected to the multilayer piezoelectric material part, and the sensor comprises a piezoelectric material and an electrode part,
wherein the multilayer piezoelectric part of the vibrator is polled in different directions and is coupled with the first layer to be expanded or contracted in the same direction, and
wherein an uppermost layer of the vibrator and an uppermost layer of the sensor with respect to a stacking direction in which the piezoelectric material and the electrode part of the vibrator and the sensor are each stacked are disposed on the same surface.

12. The MEMS senor as et forth in claim 1l, w multilayer piezoelectric part of fire vibrator comprises:
a first piezoelectric material, a second piezoelectric: material, which is stacked with the first piezoelectric material and is expanded or contracted in an opposite direction to the first piezoelectric material,
wherein the electrode part is connected to the first piezoelectric mat and the second piezoelectric material.

13. The MEMS sensor as set forth in claim 12, wherein the electrode part comprises a first electrode connected to the first piezoelectric material, a second electrode connected to the second piezoelectric material, and a third electrode disposed between the first piezoelectric material and the second piezoelectric material.

14. The MEMS sensor as set forth in claim 13, wherein with respect o the stacking direction in which the flexible substrate is supported to the support part,
the second electrode is disposed at a lower end of the vibrator and a portion thereof contacts the support part,
the second piezoelectric material is formed on an upper portion of the second electrode,
the third electrode is formed between the second piezoelectric material and the first piezoelectric material,
the first piezoelectric material is formed on an upper portion of the third electrode, and
the first electrode is formed on an upper portion of the first piezoelectric material.

15. The MEMS sensor as set forth in claim 14, wherein an electrode which is connected to the first electrode and the second electrode is applied with a voltage and a third electrode is applied with a voltage having a phase difference of 180° with respect to the voltage.

16. The MEMS sensor as set forth in claim 14, wherein an electrode in which the first electrode and the second electrode are connected is a ground electrode,

17. The MEMS sensor as set forth in claim 10, wherein the piezoelectric material of the sensor is formed in a single layer and the electrode part is formed to be stacked on one surface of the piezoelectric material.

18. The MEMS sensor as set forth in claim 10, wherein the sensor and the vibrator have the same thickness to the stacking direction in which the piezoelectric material and the electrode part are formed.

19. The MEMS sensor as set forth in claim 10, wherein the electrode part of the sensor comprises an upper electrode which is formed on one surface of the piezoelectric material, an intermediate electrode, which is fat wed on the other surface of the piezoelectric material, and a lower electrode, and wherein the intermediate electrode is connected to the lower electrode.

20. The MEMS sensor as set forth in claim 10, wherein the electrode part of the sensor includes an upper electrode, which is formed on one surface of the piezoelectric material and an intermediate electrode, which is formed on the other surface of the piezoelectric material.
